(19) United States
(12) Patent Application Publication
(10) Pub. No.: US 2002/0176227 A1
(43) Pub. Date: Nov. 28, 2002

(54) Heat dispensing device for computers

(76) Inventors: Sen-Yung Lee, Tainan City (TW); Shueei-Muh Lin, Tainan City (TW); Hsin-Mao Hsieh, Pin-Tong City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/862,334

(22) Filed: May 23, 2001

(51) Int. Cl. H05K 7/20

(52) U.S. Cl. 361/697

(57) ABSTRACT

A heat dispensing device includes a base board and a plurality of fins extend from a top of the base board and are arranged in a form of radiation. A fan is connected on the fins and has blades which extend inclinedly toward the fins from a shaft of the fan. The air flow generated by the fan blades reaches a central portion of the top of the base board to bring heat at the central portion of the base board.

### FIELD OF THE INVENTION

The present invention relates to a heat dispensing device for computers and the device includes a fan having inclined blades which generate air flow to a center of the device.

### BACKGROUND OF THE INVENTION

A conventional heat dispensing device for computers is shown in FIG. 1 and generally includes a base board 1 and a plurality of fins 2 extend from a top of the base board 1. A fan 3 is connected on the fins 2 and a CPU 10 of the computer is located at a center of the bottom of the base board 1. The rotation of the fan blades 31 generates air flow to bring the air between the fins 2 so as to reduce the temperature of the CPU 10. However, the highest temperature is captured at the bottom of the base board 1 because the CPU 10 is located at the position, the air flow cannot reach the central portion of the base board 1 so that the efficiency of dispensing heat from the CPU 10 is not satisfied.

The present invention intends to provide a heat dispensing device which brings air flow to a central portion of the base board so as to effectively bring the hear generated by the CPU away.

### SUMMARY OF THE INVENTION

In accordance with one aspect of the present invention, there is provided a heat dispensing device and comprises a base board and a plurality of fins extend from a top of the base board. A fan is connected on the fins and has blades which extend inclinedly toward the fins from a shaft of the fan.

The primary object of the present invention is to provide a heat dispensing device that has air flow passing through a central portion of the base board so as to effectively bring heat at the central portion of the base board away.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a side view to show a conventional heat dispensing device for computers;

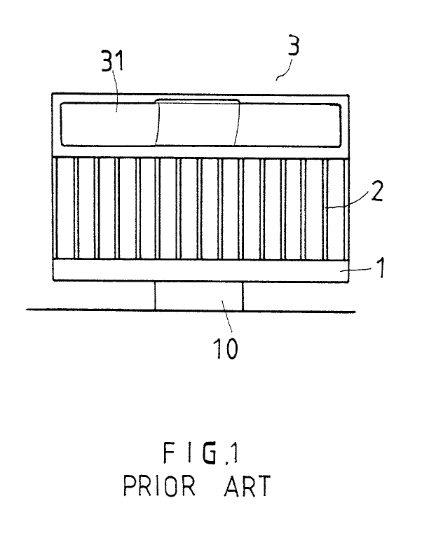

FIG. 2 is an exploded view to show a heat dispensing device for computers of the present invention, and

FIG. 3 is side view to show the heat dispensing device for computers of the present invention.

### DETAILED DESCRIPTION OF THE PREFERRED EMBODIMENT

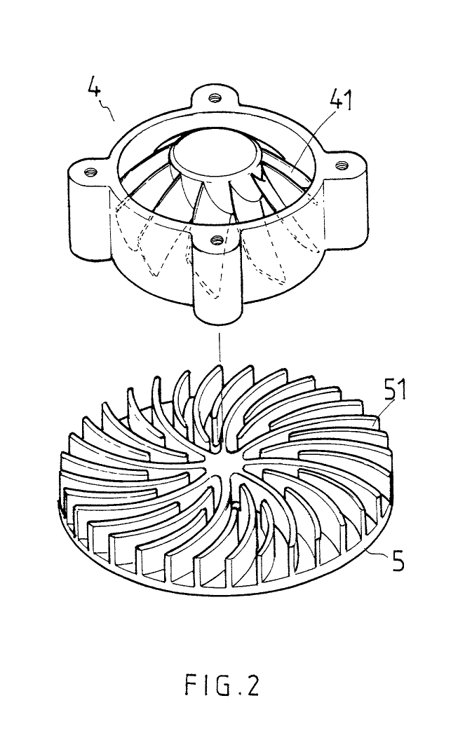

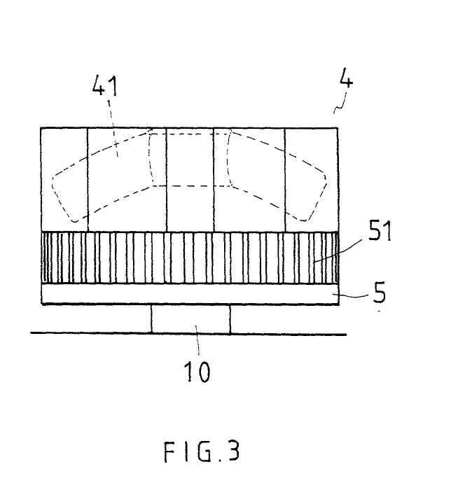

Referring to FIGS. 2 and 3, the heat dispensing device for computers of the present invention comprises a base board 5 and a plurality of fins 51 extend from a top of the base board 5. The fins 51 are arranged in a form of radiation on the base board 5. A fan 4 is connected on the fins 51 and has blades 41 which extend inclinedly toward the fins 5 from a shaft of the fan 4. Each of the fins 51 is a curve plate so that the paths defined between the fins 51 extend in the same direction with the direction of the air flow generated by the fan 4.

A CPU 10 of the computer is connected to a center of the bottom of the base board 5 and the heat created by the operation of the CPU 10 passes to the base board 5. When the fan 4 is operated, the air flow goes downward and to the central portion of the base board 5 so that the heat captured at the central portion of the base board 5 can be taken away via the paths between the fins 51.

While we have shown and described the embodiment in accordance with the present invention, it should be clear to those skilled in the art that further embodiments may be made without departing from the scope of the present invention.

What is claimed is:

1. A heat dispensing device comprising:
a base board and a plurality of fins extending from a top of said base board, and
a fan connected on said fins and having blades which extend inclinedly toward said fins from a shaft of said fan.

2. The device as claimed in claim 1, wherein said fins are arranged in a form of radiation on said base board.
